(19) United States
(12) Patent Application Publication
(10) Pub. No.: US 2025/0359484 A1
(43) Pub. Date: Nov. 20, 2025

(54) METHOD OF PROCESSING MAGNETIC FILM, METHOD OF MANUFACTURING MAGNETIC DEVICE, AND PROCESSING APPARATUS

(71) Applicant: Hitachi, Ltd., Tokyo (JP)

(72) Inventor: Masaki YAMADA, Tokyo (JP)

(21) Appl. No.: 19/073,206

(22) Filed: Mar. 7, 2025

(30) Foreign Application Priority Data
May 14, 2024 (JP) 2024-078704

(51) Int. Cl. H10N 50/01; H01J 37/32; H01L 21/467; H10N 50/10

(52) U.S. Cl. CPC H10N 50/01; H01J 37/3244; H01L 21/467; H10N 50/10; H01J 2237/334

(57) ABSTRACT

A processing method includes a first step of performing plasma etching using oxygen plasma on a magnetic device on which a magnetic film is stacked and a second step of performing gas etching using mixed gas containing oxygen and diketone after the first step, a cycle including the first step and the second step is repeated multiple times, and the mixed gas is irradiated from a side that faces a surface of the magnetic device in the second step.

### CROSS REFERENCES TO RELATED APPLICATIONS

The present application claims priority to Japanese Patent Application No. 2024-078704 filed on May 14, 2024, the disclosure of which is incorporated herein by reference.

### TECHNICAL FIELD

The present invention relates to a method of processing a magnetic film, a method of manufacturing a magnetic device, and a processing apparatus, and relates to, for example, a method of processing a magnetic film, a method of manufacturing a magnetic device, and a processing apparatus applicable to a magnetic memory.

### BACKGROUND

With the explosive increase in data processing capacity in recent years, there are urgent needs for the reduction in power consumption as well as higher speed and higher integration in semiconductor devices. Conventionally, SRAM (Static Random Access Memory) and DRAM (Dynamic Random Access Memory) have been widely used as working memory. As these devices become more miniaturized, it becomes more difficult to trap electrons, and standby power for data retention tends to increase. In order to reduce the standby power, non-volatile memories have been proposed, making it possible to significantly reduce the standby power in the standby mode.

Among the non-volatile memories, the development of STT-MRAM (Spin Transfer Torque Magnetic Random Access Memory), which has excellent processing speed and rewrite resistance, has been progressing, but there are a lot of issues in replacing SRAM and DRAM. One of the issues is the problem of high integration. Conventionally, element miniaturization in semiconductor devices has progressed by RIE (Reactive Ion Etch) processing, but it is difficult to apply the conventional RIE processing to magnetic materials used in the materials of the STT-MRAM. One of the reasons for this is that the vapor pressure of the chlorides and fluorides of magnetic bodies is high, making them difficult to sublime after chemical reactions. In addition, it has been reported that magnetic properties deteriorate due to chemical reactions in the processing of magnetic films. For example, there have been many reports of deterioration of electrical properties due to processing damage regarding the STT-MRAM using perpendicular magnetization films.

Based on such backgrounds, processing by IBE (Ion Beam Etch) using physical sputtering phenomenon has been generally used in the processing of the STT-MRAM. The processing by IBE is a processing method using physical sputtering, and for example, a method in which physical etching is promoted by irradiating the material to be etched (magnetic film) with Ar ions. As the advantage of the processing by IBE, there is no chemical damage caused by etching, and it is possible to process the materials that are difficult to process by RIE. On the other hand, the processing by IBE has the disadvantage in that particles generated by physical sputtering and adhered to the side surface of the device in ion milling cause short circuits.

For this reason, in the processing by ion milling, it is usually necessary to remove re-adhered materials on the side surface of the device by changing the incident angle of Ar ion beam. On the other hand, if the incident angle of the Ar ions is set in a direction that is not perpendicular to the film surface of the material to be etched, a shadowing effect in which the ions are blocked by structures such as mask patterns occurs, making it difficult to process between narrow-pitch patterns. With this background, the current situation is that high integration of the STT-MRAM has not progressed due to issues in the processing of magnetic films.

### SUMMARY

As mentioned above, there are many issues in applying the normal etching by RIE to the processing of magnetic films. In recent years, etching techniques using metal complex reactions have been proposed for the processing of magnetic films. For example, in the case of the etching of cobalt, as described in S. Fujisaki et. al., “Thermal-cyclic atomic layer etching of cobalt with smooth etched surface by plasma oxidation and organometallization”, Applied Physics Letters, September (2022) (Non-Patent Document 1), selective etching of difficult-to-etch materials has been successful by irradiating cobalt oxide with acetylacetone gas.

The method described in Non-Patent Document 1 is a processing method in which cobalt is oxidized with oxygen plasma and then irradiated with acetylacetone that is diketone under a constant temperature condition to promote metal complex reactions and desorption of reaction products. Non-Patent Document 1 describes a method in which cyclic processing is adopted because of the difference in the temperature range between the oxidation reaction and the desorption reaction, thereby ensuring flatness after etching. Although it is possible to control the amount of etching very precisely in this method because the etching is done at the atomic layer level, on the other hand, it also has the disadvantage of requiring a very long processing time. Therefore, it is not suitable for mass production of magnetic devices such as STT-MRAM.

The embodiments described below have been made in view of the above, and other issues and novel features will be apparent from the description of this specification and accompanying drawings.

A method of processing a magnetic film according to one embodiment includes: a first step of performing plasma etching by oxygen plasma on a workpiece on which a magnetic film is formed; and a second step of performing gas etching using mixed gas containing oxygen and diketone after the first step, a cycle including the first step and the second step is repeated multiple times, and in the second step, the mixed gas is irradiated in a first direction from a side that faces a surface of the workpiece.

A method of manufacturing a magnetic device according to one embodiment includes: a step of forming a multilayer film in which at least a fixed layer, a tunnel barrier layer, a free layer, and a mask layer are stacked in order on a substrate; a step of patterning the mask layer into a predetermined pattern; a step of processing the free layer by plasma etching using oxygen plasma using the patterned mask layer as a mask after the patterning step; a step of processing the free layer by gas etching using mixed gas containing oxygen and diketone after the step of processing the free layer by the plasma etching; a step of processing the tunnel barrier layer and the fixed layer by plasma etching using oxygen plasma after the step of processing the free layer by the gas etching; a step of processing the fixed layer by gas etching using mixed gas containing oxygen and diketone after the step of processing the tunnel barrier layer and the fixed layer by the plasma etching; a step of forming an interlayer insulating film after the step of processing the fixed layer by the gas etching; and a step of performing a planarization processing on the interlayer insulating film formed in the step of forming the interlayer insulating film.

A processing apparatus according to one embodiment includes: a vessel including a first gas inlet and a first gas outlet; a sample stage on which a workpiece is placed in the vessel; a plasma induction unit configured to induce plasma in the vessel from gas introduced from the first gas inlet; an oxygen supply unit configured to supply oxygen to the first gas inlet; a diketone supply unit configured to supply diketone to the first gas inlet; and a first regulator configured to regulate the supply of the diketone from the diketone supply unit to the first gas inlet, the first gas inlet is provided in a wall surface that faces a surface of the workpiece placed on the sample stage, the first gas outlet is provided in a wall surface that faces the wall surface in which the first gas inlet is provided, the first regulator supplies only the oxygen to the first gas inlet by regulating the supply of the diketone from the diketone supply unit when the plasma induction unit operates, and the first regulator supplies mixed gas of the oxygen and the diketone to the first gas inlet by supplying the diketone from the diketone supply unit when the plasma induction unit does not operate.

According to the embodiments above, it is possible to realize the processing suitable for mass production.

### BRIEF DESCRIPTION OF DRAWINGS

FIG. 1 illustrates a method of processing a magnetic film by a cyclic processing of an oxidation reaction and a metal complex reaction using diketone described in Non-Patent Document 1.

FIG. 2 is a schematic diagram of a processing apparatus for executing a method of processing a magnetic film according to a first embodiment.

FIG. 3 is a diagram illustrating a state in which plasma is induced in the processing apparatus in FIG. 2.

FIG. 4 is a diagram illustrating a state in which no plasma is induced in the processing apparatus in FIG. 2.

FIG. 5 is a chart diagram illustrating processing conditions in the processing apparatus in FIG. 2.

FIG. 6 is a diagram illustrating a processing example of a magnetic device in the processing apparatus in FIG. 2.

FIG. 7 is a schematic diagram of a processing apparatus for executing a method of processing a magnetic film according to a second embodiment.

FIG. 8 is a chart diagram illustrating processing conditions in the processing apparatus in FIG. 7.

FIG. 9 is a diagram illustrating a processing example of a magnetic device in the processing apparatus in FIG. 7.

FIG. 10 is a diagram illustrating a processing example of a magnetic device in the processing apparatus in FIG. 7.

FIG. 11 is a schematic diagram of a processing apparatus for executing a method of processing a magnetic film according to a third embodiment.

FIG. 12A is a diagram illustrating a state in which plasma is induced in the processing apparatus in FIG. 11.

FIG. 12B is a diagram illustrating a state in which no plasma is induced in the processing apparatus in FIG. 11.

FIG. 13 is a diagram illustrating a state in which no plasma is induced in the processing apparatus in FIG. 11.

FIG. 14 is a diagram illustrating a processing example of a magnetic device in the processing apparatus in FIG. 11.

FIG. 15 is a diagram illustrating a processing example of a magnetic device in the processing apparatus in FIG. 11.

FIG. 16 illustrates the results of etching reaction of cobalt using oxygen and diketone.

FIG. 17 is a diagram illustrating an effect in magnetic device patterns.

FIG. 18 is a diagram illustrating the results of elemental analysis on FIG. 17.

FIG. 19 is a schematic diagram illustrating a manufacturing process of MTJ element.

### DETAILED DESCRIPTION OF THE INVENTION

In the following embodiments, when necessary for convenience, a description divided into a plurality of sections or embodiments will be given, but the sections or embodiments are not irrelevant to each other unless otherwise specified, and one is in a relationship of modification, details, supplementary description, and the like of a part or all of the other. In addition, in the following embodiments, when referring to the number of elements and the like (including number, numerical value, amount, range, and the like), the number is not limited to a specific number unless otherwise specified or clearly limited to the specific number in principle, and the number may be equal to or more than the specific number or may be equal to or less than the specific number.

Furthermore, in the following embodiments, it goes without saying that the components (including element steps and the like) are not necessarily essential unless otherwise specified or considered to be obviously essential in principle. Similarly, in the following embodiments, when referring to the shape, positional relationship, and the like of the components and the like, it is assumed to include those substantially approximate or similar to the shape and the like unless otherwise specified or unless clearly considered otherwise in principle. The same applies to the above numerical value and range.

Hereinafter, embodiments of the present invention will be described in detail with reference to the drawings. Note that, in all the drawings for describing the embodiments, the same members are denoted by the same reference characters, and repetitive description thereof will be omitted.

### Outline of Embodiments

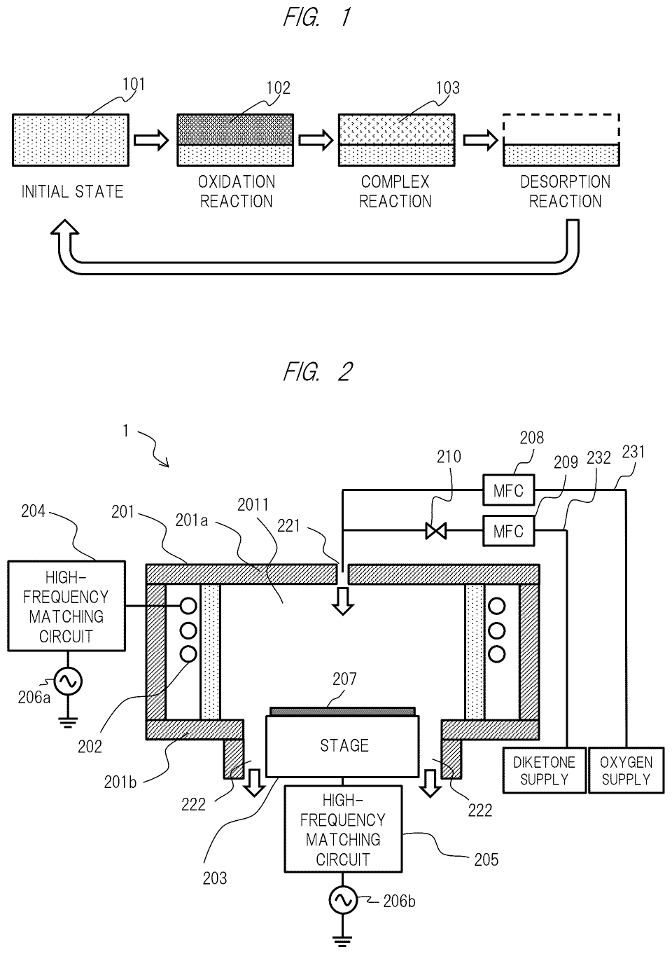

In the following embodiments, a method of processing a magnetic film in which anisotropic processing using oxygen ions and isotropic processing by metal complex formation are combined will be proposed. FIG. 1 illustrates a method of processing a magnetic film by a cyclic processing of an oxidation reaction and a metal complex reaction using diketone described in Non-Patent Document 1.

First, in a first step, a surface of a magnetic film 101 in an initial state is oxidized by oxidizing plasma or thermal oxidation to form an oxidized magnetic film layer 102. In a next second step, the oxidized magnetic film layer 102 is irradiated with diketone to cause a complex reaction, thereby forming a metal complex layer 103. According to Non-Patent Document 1, acetylacetone (hacac) is known to be effective for cobalt. In a next third step, the formed metal complex layer 103 is desorbed from the magnetic film 101 by ion irradiation and thermal treatment. According to Non-Patent Document 1, the metal complex of cobalt is known as Co(acac)₂, and it is reported that the metal complex reaction and desorption reaction occur simultaneously in the temperature range of 200 to 250° C.

By repeating the oxidation reaction, the metal complex reaction, and the desorption reaction in this way, it is possible to etch the magnetic film. However, in the method according to Non-Patent Document 1, reactions occur at the atomic layer level, and the etching speed is a bottleneck. Therefore, in the following embodiments, a magnetic film is irradiated with mixed gas of oxygen and diketone at once, thereby realizing the high-speed etching of the magnetic film.

### First Embodiment

FIG. 2 illustrates a schematic diagram of a processing apparatus for executing a method of processing a magnetic film according to this embodiment. As illustrated in FIG. 2, a processing apparatus 1 includes a vacuum vessel 201, an antenna coil 202, a stage 203, high-frequency matching circuits 204 and 205, high-frequency power sources 206a and 206b, MFCs (flow controllers) 208 and 209, a vacuum valve 210, and pipes 231 and 232.

The vacuum vessel 201 has a processing chamber 2011 which is a space in which a workpiece 207 is placed and plasma is generated. In the processing chamber 2011, the stage 203 on which the workpiece 207 is placed is installed. Also, the vacuum vessel 201 is provided with an inlet 221 to which the pipe 231 described later is connected and through which oxygen gas and mixed gas described later is introduced into the processing chamber 2011. Further, the vacuum vessel 201 is provided with an outlet 222 through which the gas introduced from the inlet 221 is exhausted. The inlet 221 is provided in a wall surface 201a that faces a surface of the workpiece 207 placed on the stage 203. The outlet 222 is provided in a wall surface 201b that faces the wall surface 201a. Namely, the inlet 221 irradiates the gas in a first direction from the side that faces the surface of the workpiece 207. The irradiated gas is exhausted from the outlet 222 in the same direction as the first direction.

The antenna coil 202 is a coil (plasma induction unit) for inducing plasma in the vacuum vessel 201 (inside the processing chamber). In this embodiment, an example of an ICP (Inductively Coupled Plasma) method using the antenna coil 202 that is a high-frequency induction coil is illustrated, but the plasma generation method is not necessarily limited to this method.

In this embodiment, the stage 203 is composed of, for example, an electrostatic chuck. As described above, the stage 203 is a sample stage configured to fix the placed workpiece 207. In addition, the stage 203 has a built-in heater for heating the placed workpiece 207. However, the heating of the workpiece 207 is not limited to contact heating such as a heater, and may be non-contact heating such as irradiation with an infrared halogen lamp.

The high-frequency power source 206a is connected to the high-frequency matching circuit 204, and the high-frequency matching circuit 204 applies a high-frequency voltage to the antenna coil 202. The high-frequency power source 206a is a power source for supplying source power that generates plasma in the vacuum vessel 201 (processing chamber 2011). The high-frequency power source 206b is connected to the high-frequency matching circuit 205, and the high-frequency matching circuit 205 applies a high-frequency voltage to the stage 203. The high-frequency power source 206b is a power source for applying a bias electric field to the workpiece 207.

The MFC 208 is provided midway through the pipe 231 connected to the inlet 221. The MFC 208 adjusts the flow rate of oxygen gas as described below. In other words, the MFC 208 serves as an oxygen supply unit configured to supply oxygen to the inlet 221. The MFC 209 is provided on an upstream side of the pipe 232. The MFC 209 adjusts the flow rate of diketone as described below. Further, the MFC 209 serves as a diketone supply unit configured to supply diketone to the inlet 221.

The vacuum valve 210 is provided on a downstream side relative to the MFC 209 on the pipe 232. The vacuum valve 210 is controlled to be open when no plasma is induced, and closed when plasma is induced. The vacuum valve 210 may be of any type, such as a compressed air valve or an electromagnetic valve. Namely, the vacuum valve 210 serves as a first regulator configured to regulate the supply from the MFC 209 to the inlet 221.

The pipe 231 is a pipe configured to introduce oxygen or mixed gas of oxygen and diketone described later into the vacuum vessel 201. Oxygen gas is supplied to the pipe 231 from the upstream side. Then, the flow rate of the oxygen gas is adjusted by the MFC 208 installed midway through the pipe 231, and the adjusted oxygen gas is introduced into the vacuum vessel 201 from the inlet 221. Also, the pipe 232 is connected to the pipe 231 on the downstream side relative to the MFC 208. Therefore, the pipe 231 can mix oxygen and diketone from the pipe 232 and supply the mixed gas to the inlet 221.

The pipe 232 is a pipe configured to supply diketone to the vacuum vessel 201. Diketone is supplied to the pipe 232 from the upstream side. Then, the flow rate of the diketone is adjusted by the MFC 209 provided midway through the pipe 232, and the diketone is supplied to the inlet 221 through the pipe 231 when the vacuum valve 210 is controlled to be open. Therefore, oxygen gas or mixed gas of oxygen and diketone is introduced from the inlet 221 into the vacuum vessel 201 in accordance with the operation of the processing apparatus 1.

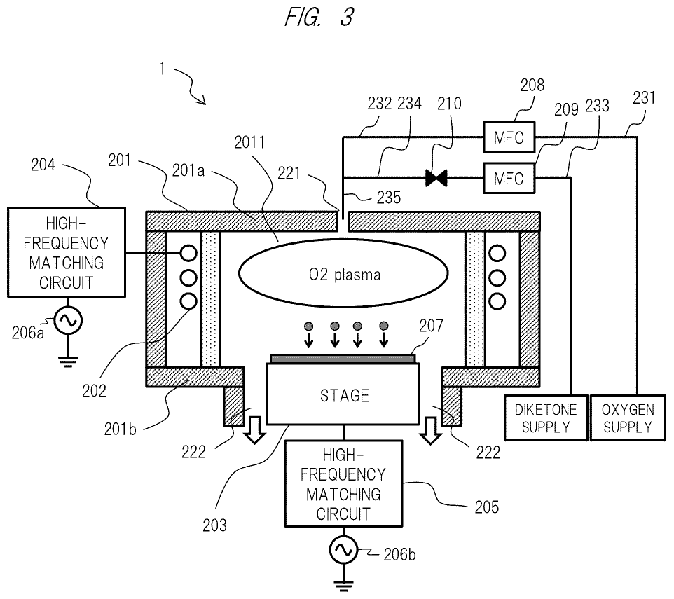

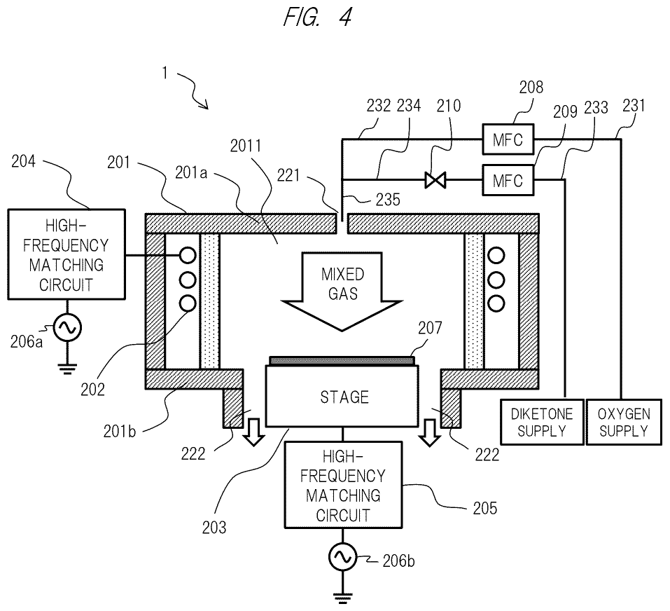

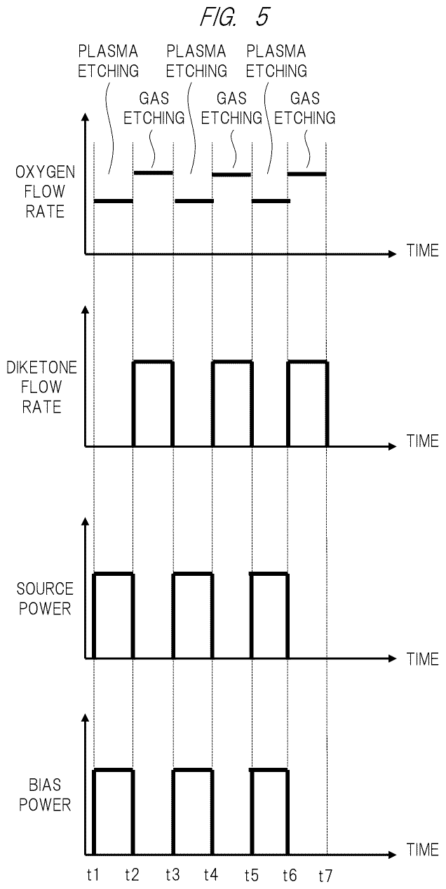

Next, a processing method using the processing apparatus 1 will be described with reference to FIG. 3 and FIG. 4. FIG. 3 illustrates a state in which plasma is induced. In FIG. 3, when a high-frequency voltage is applied to the antenna coil 202 from the high-frequency matching circuit 204 in the state in which the vacuum valve 210 is controlled to be closed and only oxygen gas adjusted by the MFC 208 is introduced, oxygen plasma is induced in the processing chamber 2011. Namely, the vacuum valve 210 regulates the supply of diketone from the MFC 209 so as to supply only oxygen to the inlet 221 when the antenna coil 202 operates.

Note that the frequency and output intensity of the high-frequency power source 206a for inducing plasma may be determined as appropriate. When a high-frequency voltage is applied to the stage 203 from the high-frequency matching circuit 205 in the state in which oxygen plasma is induced, oxygen ions are accelerated from the oxygen plasma perpendicularly to the workpiece 207. In general, the incident speed of oxygen ions can be controlled by the magnitude of the bias electric field applied to the stage 203.

FIG. 4 illustrates a state in which no plasma is induced. As illustrated in FIG. 4, for example, when no high-frequency voltage is applied to the antenna coil 202, the vacuum valve 210 is controlled to be open, and oxygen gas and diketone are simultaneously supplied to the vacuum vessel 201. In other words, the mixed gas of oxygen gas and diketone is supplied into the vacuum vessel 201. Namely, the vacuum valve 210 supplies diketone from the MFC 209 so as to supply the mixed gas of oxygen and diketone to the inlet 221 when the antenna coil 202 does not operate.

Further, in the state illustrated in FIG. 4, the temperature of the workpiece 207 on the stage 203 is kept at a predetermined temperature. For example, when the workpiece 207 to be processed is cobalt and acetylacetone is selected as the diketone, the temperature of about 200 to 400° C. is appropriate as the temperature of the workpiece 207 during gas etching. In addition, in this step, the pressure inside the vacuum vessel 201 is ideally kept constant by adjusting the amount of exhaust, and the pressure range of about 100 to 5000 Pa is presented as an example. Under such conditions, gas etching using the mixed gas of oxygen and diketone is possible.

Next, FIG. 5 illustrates an example of a chart diagram of the above-mentioned processing conditions. FIG. 5 illustrates the temporal changes of the oxygen flow rate, diketone flow rate, source power, and bias power from the top. In addition, the plasma etch (plasma etching) illustrated in FIG. 5 corresponds to the state in which the plasma is induced as illustrated in FIG. 3, and the gas etch (gas etching) illustrated in FIG. 5 corresponds to the state in which no plasma is induced as illustrated in FIG. 4.

As illustrated in FIG. 5, plasma etching is performed as the first step between time t1 and time t2, between time t3 and time t4, and between time t5 and time t6. Meanwhile, gas etching is performed as the second step between time t2 and time t3, between time t4 and time t5, and between time t6 and time t7. Therefore, plasma etching and gas etching are performed alternately. Alternatively, it can be said that a cycle in which plasma etching and gas etching are performed in this order is repeated multiple times.

As illustrated in FIG. 5, oxygen gas is constantly supplied, but the gas flow rate thereof is controlled by the MFC 208 in the plasma etching illustrated in FIG. 3 and the gas etching illustrated in FIG. 4 so as to be optimized for each etching step. Meanwhile, diketone is supplied only when the source power for plasma induction and the bias power are not supplied (t2-t3, t4-t5, and t6-t7). Also, the flow rate thereof is controlled by the MFC 209 so as to have an appropriate mixture ratio with oxygen. By the operation in this sequence, it becomes possible to alternately perform the plasma etching and the gas etching, enabling anisotropic processing by oxygen ions in the plasma etching step and isotropic processing in the gas etching step. Note that the time for each step can be determined as appropriate depending on the workpiece 207 to which it is applied.

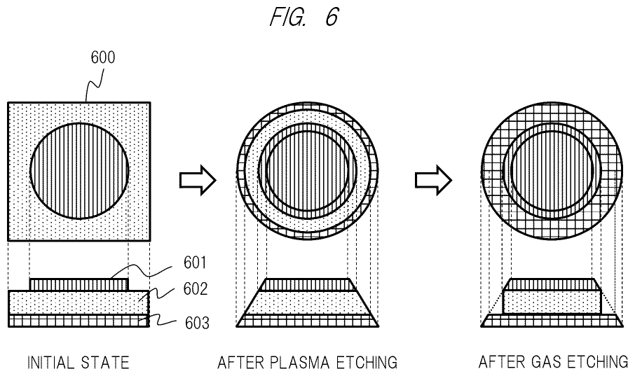

FIG. 6 illustrates a processing example of a magnetic device when the above-mentioned processing method is applied. First, the left side of FIG. 6 illustrates the initial state of a magnetic device 600. In the magnetic device 600, a magnetic film 602 and a non-magnetic metal oxide film 601 are stacked in this order on a non-magnetic metal film 603. Note that the non-magnetic metal oxide film 601 is patterned in advance.

Examples of the non-magnetic metal oxide film 601 include materials that can be formed as non-magnetic oxide films, such as aluminum oxide, silicon oxide, and magnesium oxide. In the plasma etching step, the magnetic film 602 is etched by oxygen ions using the non-magnetic metal oxide film 601 as a mask, but since a part of the etched magnetic material adheres to the sidewall of the pattern, the processed shape becomes a tapered shape (center of FIG. 6). In addition, since the non-magnetic metal oxide film 601 has high etching resistance against oxygen ions, the reduction in mask height is small even in the plasma etching step. Thereafter, the mixed gas of oxygen and diketone is irradiated by downflow. In other words, the mixed gas is irradiated from a side that faces the surface of the magnetic device 600 which is the workpiece to be processed. Then, a metal complex reaction selectively occurs only in the tapered portion, with the result that the taper angle of the sidewall portion approaches vertical (right side of FIG. 6).

This is because the mixed gas is irradiated only to the tapered portion that is not covered with the non-magnetic metal oxide film 601, and the metal complex reaction proceeds preferentially. In the gas etching step using oxygen and diketone, the etching selectivity ratio to the non-magnetic metal film 603 is important, and it is possible to remove only the tapered portion of the magnetic film 602 by appropriately selecting the target material. As an example thereof, when cobalt is used as the magnetic film 602 and tantalum, tungsten, titanium, or the like is used as the non-magnetic metal film 603, the etching reaction by the metal complex reaction using acetylacetone as diketone occurs only with cobalt, enabling the high selective etching of the magnetic film 602.

According to this embodiment, the first step of performing plasma etching using oxygen plasma and the second step of performing the gas etching using the mixed gas containing oxygen and diketone after the first step are performed on the magnetic device 600 on which the magnetic film 602 is formed. Then, the cycle including the first step and the second step is repeated multiple times. In the second step, the mixed gas is irradiated from the side that faces the surface of the magnetic device 600 (downflow). Therefore, it is possible to selectively remove the tapered portion of the magnetic device 600. Thus, the improvement by the removal of the tapered shape in the magnetic device 600 makes it possible to achieve, for example, high integration. Furthermore, by performing the gas etching using the mixed gas, etching can be performed at a higher speed than the method of Non-Patent Document 1, so that processing suitable for mass production can be realized.

In addition, since the mixed gas irradiated by downflow is exhausted from the outlet 222, it can be efficiently exhausted without changing the gas flow.

### Second Embodiment

Next, a second embodiment will be described. In the following, the description overlapping with the above-mentioned embodiment will be omitted in principle.

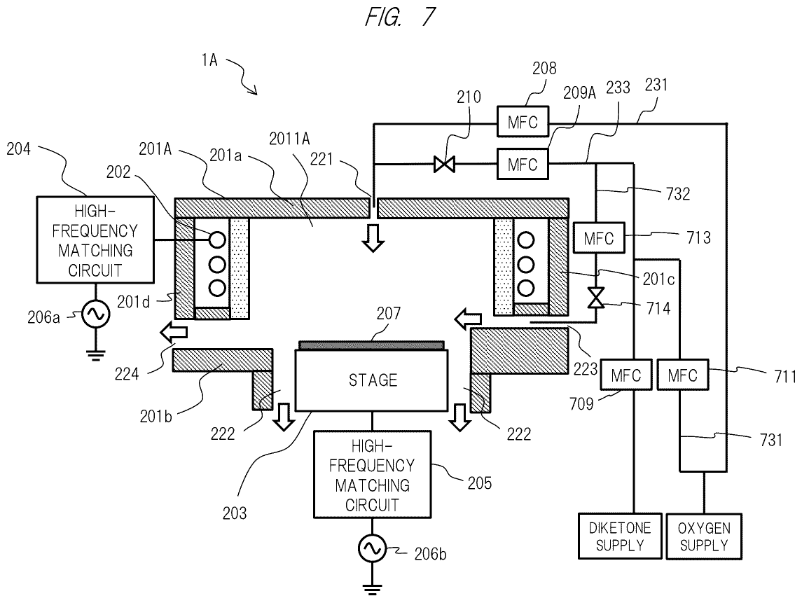

FIG. 7 illustrates a schematic diagram of a processing apparatus 1A according to this embodiment. In the processing apparatus 1A of this embodiment, the vacuum vessel 201 in the processing apparatus 1 illustrated in FIG. 2 is changed to a vacuum vessel 201A. Furthermore, MFCs 709, 711, and 713, a vacuum valve 714, and pipes 731 and 732 are added. Also, the MFC 209 is changed to an MFC 209A.

The vacuum vessel 201A is provided with an inlet 223 and an outlet 224 in addition to the configuration of the vacuum vessel 201 illustrated in FIG. 2. The inlet 223 is provided in a wall surface 201c that is perpendicular to the wall surface 201b. The outlet 224 is provided in a wall surface 201d that faces the wall surface 201c. The pipe 732 is connected to the inlet 223, through which mixed gas of oxygen and diketone is introduced into a processing chamber 2011A. The outlet 224 exhausts the gas introduced from the inlet 223. It is preferable that the inlet 223 and the outlet 224 in the wall surfaces 201c and 201d are each provided at a position (height) close to the stage 203.

The MFC 709 is provided on an upstream side relative to the MFC 209A on the pipe 233. The MFC 709 adjusts the flow rate of diketone as described below. The MFC 209A adjusts the flow rate of mixed gas of oxygen gas and diketone. The MFC 711 is provided midway through the pipe 731 and adjusts the flow rate of oxygen gas. The MFC 713 is provided midway through the pipe 732 and adjusts the flow rate of the mixed gas of oxygen gas and diketone.

The vacuum valve 714 is provided on a downstream side relative to the MFC 713 on the pipe 732. The vacuum valve 714 is controlled to be open when no plasma is induced, and closed when plasma is induced. As with the vacuum valve 210, the vacuum valve 714 may be of any type, such as a compressed air valve or an electromagnetic valve. Namely, the vacuum valve 714 serves as a second regulator configured to regulate the introduction of the mixed gas from the inlet 223.

The pipe 731 branches off from the pipe 231 on an upstream side relative to the MFC 208 provided on the pipe 231. The pipe 731 joins the pipe 233 between the MFC 209A and the MFC 709 provided on the pipe 233. The pipe 732 branches off from the pipe 233 between the junction of the pipe 233 and the pipe 731 and the MFC 209A. The pipe 732 is connected to the inlet 223, and introduces the mixed gas branched off from the pipe 233 into the vacuum vessel 201A through the inlet 223.

While the processing apparatus 1 illustrated in FIG. 2 has only one gas inlet, the processing apparatus 1A illustrated in FIG. 7 has multiple gas inlets. In the processing apparatus 1A, in addition to the inlet 221 (first gas inlet) configured to introduce oxygen gas or mixed gas of oxygen and diketone into the vacuum vessel 201A, the inlet 223 (second gas inlet) configured to introduce mixed gas is provided. Also, the outlet 222 (first gas outlet) and the outlet 224 (second gas outlet) are provided so as to correspond to the inlets 221 and 223, respectively. The outlet 222 is provided on a side that faces the inlet 221, and the outlet 224 is provided on a side that faces the inlet 223. Therefore, the inlet 223 can introduce (irradiate) the mixed gas in a second direction different from that of the inlet 221. In FIG. 7, the mixed gas can be irradiated from the lateral side of the workpiece 207 placed on the stage 203.

Also, the direction of the gas flow in the vacuum vessel 201A can be adjusted by the MFCs 209A and 713. In addition, the mixing ratio of the mixed gas can be adjusted by the MFCs 709 and 711.

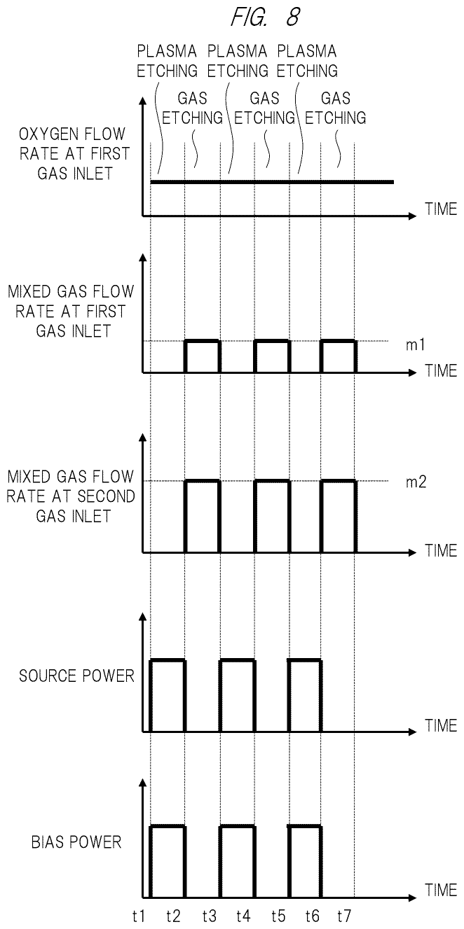

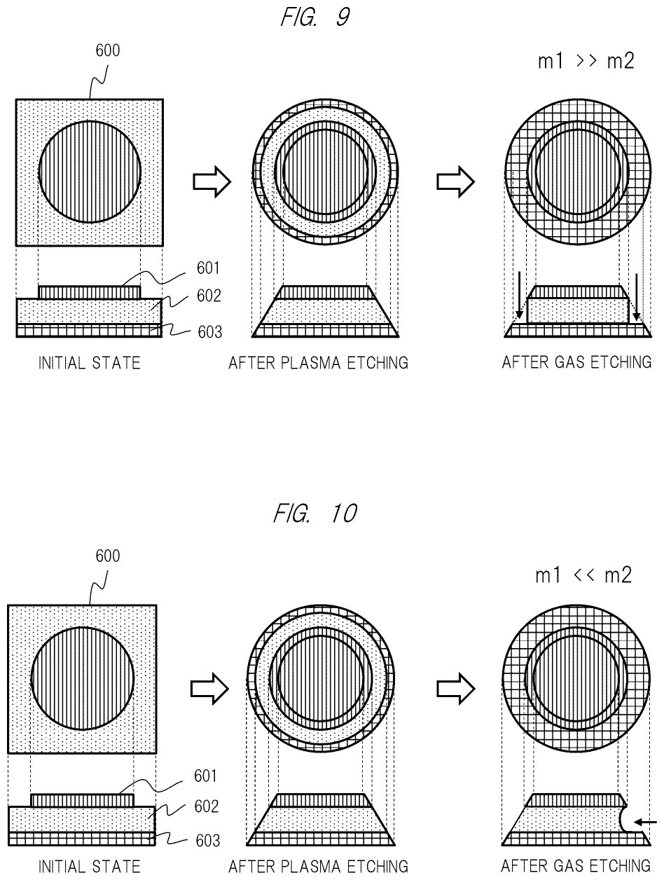

FIG. 8 illustrates an example of a chart diagram of processing conditions using the processing apparatus 1A of this embodiment. FIG. 9 illustrates the temporal changes of the oxygen flow rate at the first gas inlet (inlet 221), the mixed gas flow rate at the first gas inlet, the mixed gas flow rate at the second gas inlet (inlet 223), source power, and bias power from the top.

In the example of FIG. 8, the flow rate of oxygen flowing into the first gas inlet (inlet 221) is a constant value regardless of whether the source power and the bias power are on or off. On the other hand, the mixed gas flowing into the first gas inlet and the second gas inlet is introduced only when the source power and the bias power are off. Namely, the vacuum valve 714 regulates the introduction of the mixed gas from the inlet 223 when the antenna coil 202 operates, and allows the mixed gas to be introduced from the inlet 223 when the antenna coil 202 does not operate.

Furthermore, the flow rate of the mixed gas flowing into the first gas inlet is defined as m1 and the flow rate of the mixed gas flowing into the second gas inlet is defined as m2. When m1>>m2, the mixed gas flow from the first gas inlet (inlet 221) is dominant. Conversely, when m1<<m2, the influence of the mixed gas from the second gas inlet (inlet 223) is dominant.

In the case of FIG. 8 as well, plasma etching is performed between time t1 and time t2, between time t3 and time t4, and between time t5 and time t6 as with FIG. 5. Meanwhile, gas etching is performed between time t2 and time t3, between time t4 and time t5, and between time t6 and time t7. Therefore, plasma etching and gas etching are performed alternately.

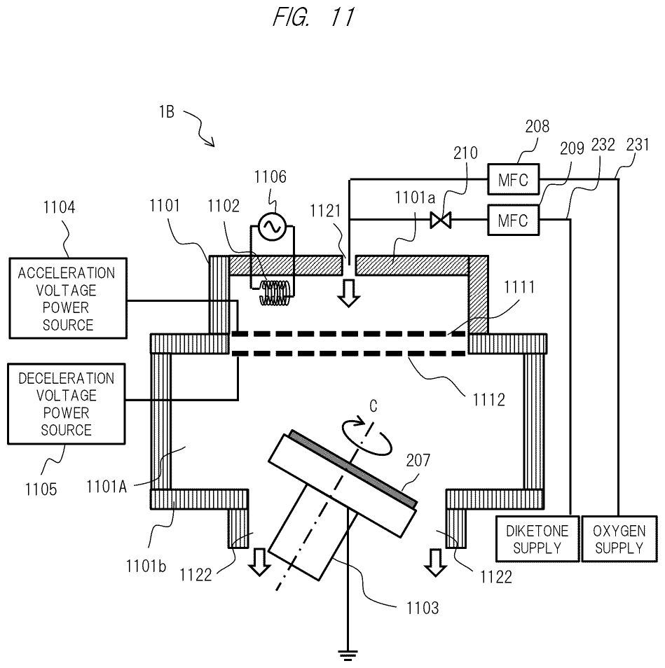

FIG. 9 and FIG. 10 illustrate a processing example of a magnetic device when the processing method of this embodiment is applied. FIG. 9 and FIG. 10 illustrate the initial state of the magnetic device 600 on the left side thereof as with FIG. 6, and the configuration (material and others) of the magnetic device 600 to be processed is the same as that in FIG. 6.

In FIG. 9, the plasma etching (center of FIG. 9) is the same as that in FIG. 6. Also, in the gas etching step on the right side of FIG. 9, under the condition of m1>>m2, only the tapered portion of the magnetic film 602 (indicated by arrows in the drawing) can be etched in the same manner as described in FIG. 6.

In FIG. 10, the plasma etching (center of FIG. 10) is the same as that in FIG. 6. Also, in the gas etching step on the right side of FIG. 10, under the condition of m1<<m2, it is possible to selectively etch the sidewall portion of the magnetic film 602 (indicated by an arrow in the drawing) in accordance with the relative angle between the second gas inlet and the magnetic device 600. Therefore, in the processing of the magnetic device 600, it is possible to control the processed shape as desired by changing the ratio of the flow rates of the mixed gases flowing through the first gas inlet and the second gas inlet.

According to this embodiment, the processing apparatus 1A is provided with the inlet 223 and the outlet 224 such that the mixed gas of oxygen and diketone can be irradiated from the lateral side of the workpiece 207 (magnetic device 600) through the inlet 223. Therefore, it is possible to control the processed shape as desired by changing the ratio of the mixed gas irradiated from above the workpiece 207 and the mixed gas irradiated from the lateral side.

In this embodiment, one inlet 223 is provided as the second gas inlet, but the second gas inlet may be additionally provided at another position.

### Third Embodiment

Next, a third embodiment will be described. In the following, the description overlapping with the above-mentioned embodiments will be omitted in principle.

FIG. 11 illustrates a schematic diagram of a processing apparatus 1B according to this embodiment. This embodiment is an application example to a plasma processing apparatus using an ion beam. The processing apparatus 1B includes a vacuum vessel 1101, a filament 1102, a rotating stage 1103, an acceleration voltage power source 1104, a deceleration voltage power source 1105, an AC power source 1106, an acceleration grid 1111, a deceleration grid 1112, the MFCs 208 and 209, the vacuum valve 210, and the pipes 231 and 232.

In the configuration mentioned above, the MFCs 208 and 209, the vacuum valve 210, and the pipes 231 and 232 are the same as those in the first embodiment. The vacuum vessel 1101 has a processing chamber 1101A which is a space in which the workpiece 207 is placed and plasma is generated. In the processing chamber 1101A, the filament 1102, the acceleration grid 1111, and the deceleration grid 1112 are provided on the side of a gas inlet 1121 described later. Also, in the processing chamber 1101A, the rotating stage 1103 on which the workpiece 207 is placed is installed on the side of a gas outlet 1122 described later. Further, the vacuum vessel 1101 is provided with the inlet 1121 to which the pipe 231 is connected and through which oxygen gas and mixed gas are introduced into the processing chamber 1101A. In addition, the vacuum vessel 1101 is provided with the outlet 1122 through which the gas introduced from the inlet 1121 is exhausted. The inlet 1121 is provided in a wall surface 1101a that faces a surface of the workpiece 207 placed on the rotating stage 1103. The outlet 1122 is provided in a wall surface 1101b that faces the wall surface 1101a.

The filament 1102 is provided in the vacuum vessel 1101 (processing chamber 1101A). The filament 1102 functions as a plasma ignition source and induces plasma by the power supplied from the AC power source 1106. The acceleration voltage power source 1104 is electrically connected to the acceleration grid 1111. The deceleration voltage power source 1105 is electrically connected to the deceleration grid 1112. The acceleration grid 1111 and the deceleration grid 1112 function as acceleration units that accelerate ions generated in the induced plasma.

The rotating stage 1103 is configured to be able to rotate around a rotation axis C that extends in a direction perpendicular to the placement surface on which the workpiece 207 is placed. The rotating stage 1103 fixes the workpiece 207 by, for example, a mechanical chuck. The rotating stage 1103 is configured to be able to change the angle of the rotation axis C from the direction coaxial with the inlet 1121 (the direction in which ions are accelerated and travel). In addition, since the rotating stage 1103 is electrically grounded, the accelerated ions can cause a sputtering phenomenon on the workpiece 207.

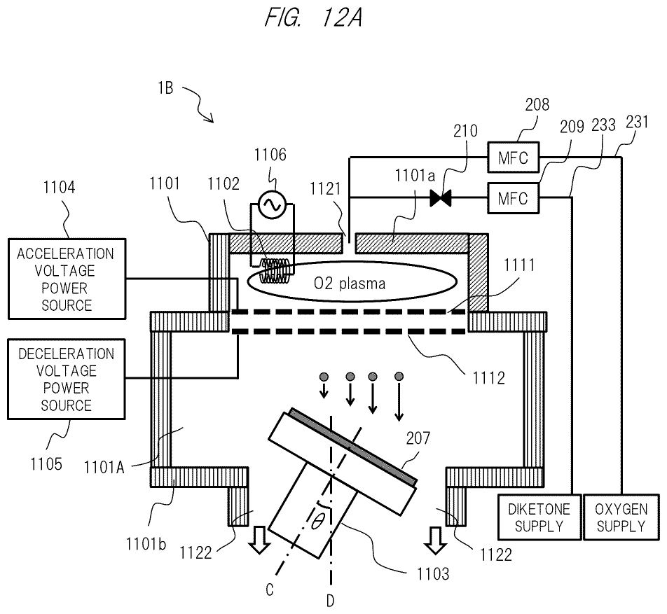

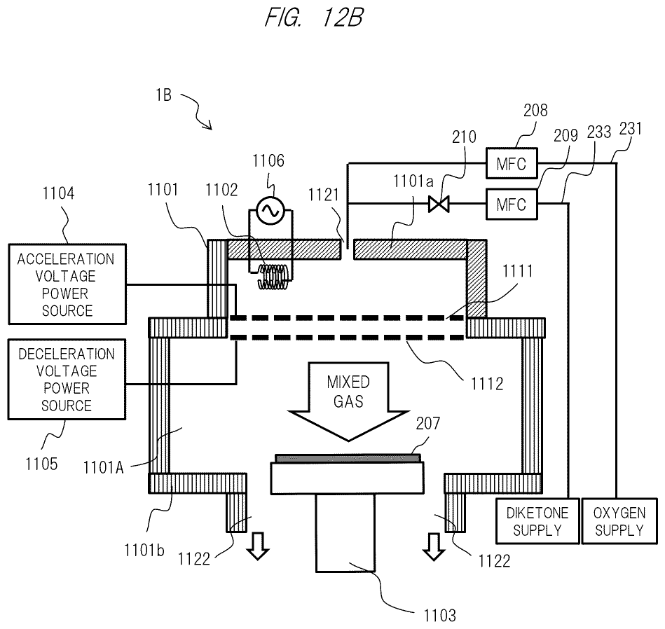

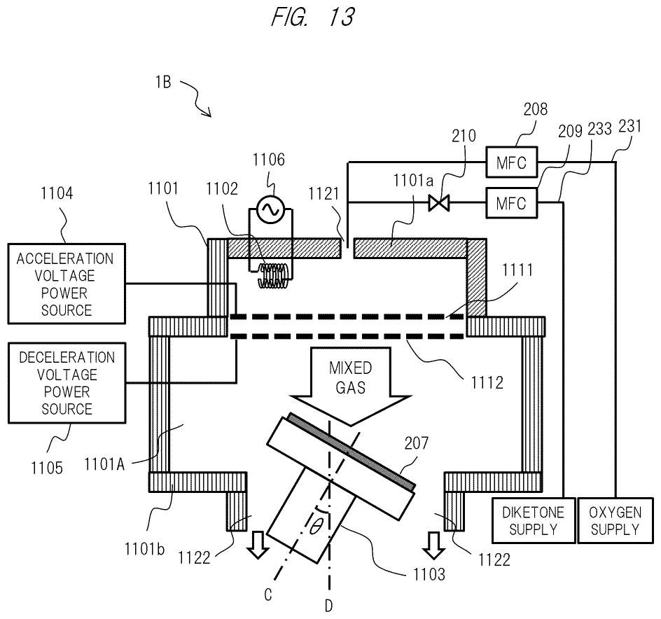

Next, a processing method using the processing apparatus 1B will be described with reference to FIG. 12 and FIG. 13. FIG. 12A illustrates a state in which plasma is induced. In FIG. 12A, when the AC power source 1106 supplies power to the filament 1102 in the state in which the vacuum valve 210 is controlled to be closed and only oxygen gas adjusted by the MFC 208 is introduced, oxygen plasma is induced in the vacuum vessel 1101. Then, by applying appropriate acceleration voltage and deceleration voltage from the acceleration voltage power source 1104 and the deceleration voltage power source 1105, physical sputter etching (plasma etching) using oxygen ions becomes possible. By setting the angle of the rotating stage 1103 to an appropriate value, it is possible to reduce the re-adhered materials due to the physical sputter etching. When the relative angle between the ion traveling direction (illustrated by a dot-dashed line D in FIG. 12A) and the rotation axis C of the rotating stage 1103 is defined as θ, it is generally preferable that θ is set to 30 to 60 degrees, but it may be determined as appropriate depending on the material of the workpiece 207 and the like. FIG. 12A illustrates the case in which the relative angle is 30 degrees.

FIG. 12B illustrates a state in which no plasma is induced. As illustrated in FIG. 12B, for example, when power is not supplied from the AC power source 1106 to the filament 1102, the vacuum valve 210 is controlled to be open, and oxygen gas and diketone are simultaneously supplied to the vacuum vessel 1101. Also, in FIG. 12B, the above-mentioned relative angle θ is set to 0 degrees.

FIG. 13 illustrates a state in which no plasma is induced as with FIG. 12B. The state in which plasma is induced may be, for example, the same as that in FIG. 12A. In FIG. 13, the above-mentioned relative angle is 30 degrees.

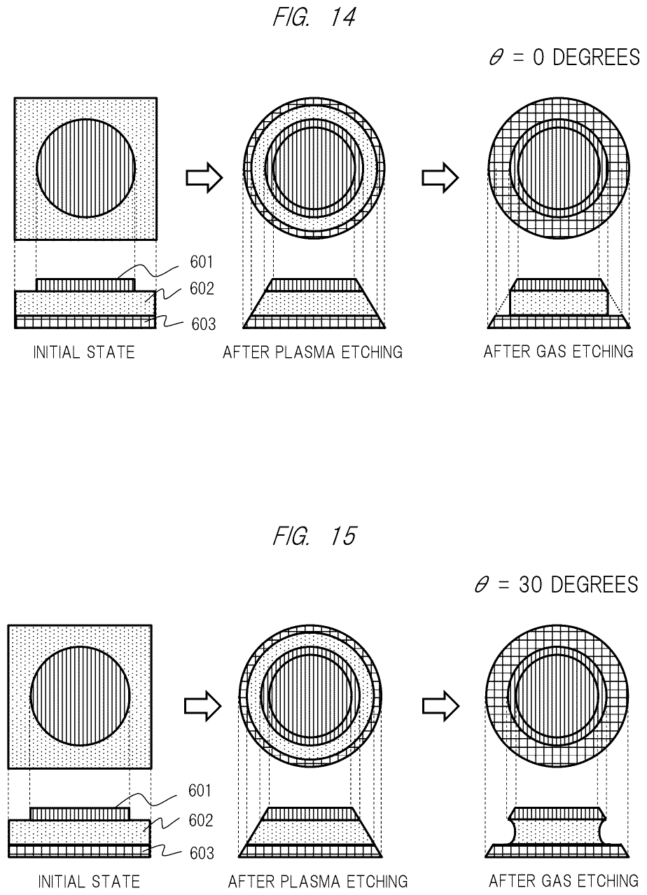

FIG. 14 and FIG. 15 illustrate a processing example of a magnetic device when the processing method of this embodiment is applied. FIG. 14 and FIG. 15 illustrate the initial state of the magnetic device 600 on the left side thereof as with FIG. 6, and the configuration (material and others) of the magnetic device 600 to be processed is the same as that in FIG. 6.

In FIG. 14, the plasma etching (center of FIG. 14) is the same as that in FIG. 6. In the gas etching step on the right side of FIG. 14, etching is performed while rotating the rotating stage 1103 under the condition of the relative angle θ=0 degrees, whereby only the tapered portion of the magnetic film 602 can be etched in the same manner as described in FIG. 6.

In FIG. 15, the plasma etching (center of FIG. 10) is the same as that in FIG. 6. Then, in the gas etching step on the right side of FIG. 15, etching is performed while rotating the rotating stage 1103 under the condition of the relative angle θ=30 degrees, whereby the sidewall portion of the magnetic film 602 can be selectively etched.

According to this embodiment, it is possible to control the processed shape as desired by changing the angle of the rotating stage 1103 during the gas etching.

### EXAMPLE

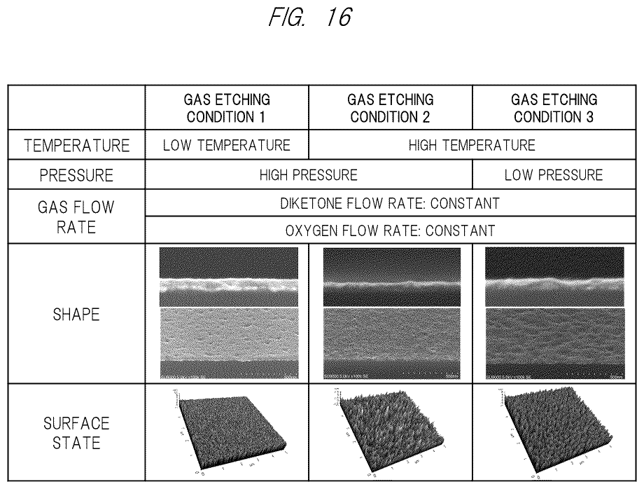

Here, FIG. 16 illustrates the results of the etching reaction of cobalt using oxygen and diketone. The following three conditions were adopted in this example. Gas etching condition 1 (hereinafter referred to as condition 1) is a low temperature (200° C.) and a high pressure (1000 Pa). Gas etching condition 2 (hereinafter referred to as condition 2) is a high temperature (400° C.) and a high pressure (1000 Pa). Gas etching condition 3 (hereinafter referred to as condition 3) is a high temperature (400° C.) and a low pressure (100 Pa). The gas flow rates of both diketone and oxygen were constant.

The photographs on an upper row presented as the shape in FIG. 16 illustrate the cross section, and those on a lower row illustrate the surface state. Also, the surface state in FIG. 16 illustrates the analysis results by AFM (atomic force microscope). As is clear from these photographs and analysis results, the etching amount and surface state differed depending on the processing conditions. In the condition 1, surface oxidation was dominant, and the etching phenomenon of cobalt was not observed. On the other hand, it was found that the film thickness of the cobalt decreased after etching and the etching reaction proceeded under the conditions 2 and 3 which were high temperature and high pressure and high temperature and low pressure. In addition, when comparing the conditions 2 and 3, it was found that the etching amount was almost the same, but the surface was smooth when the pressure was low. From the above results, it was found that the condition 3 was the most appropriate condition among the three conditions used in this example.

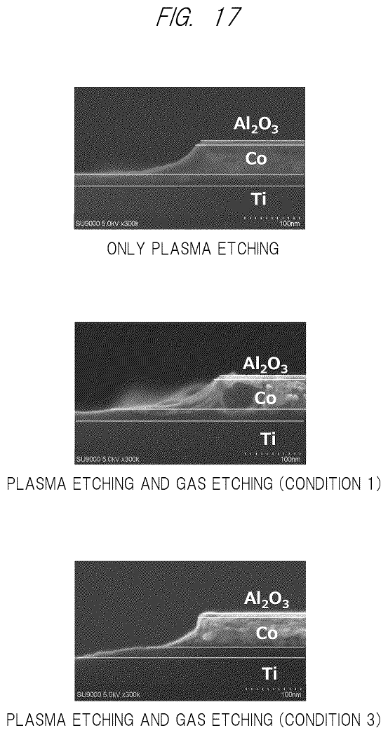

Next, the effect on the magnetic device pattern was verified (see FIG. 17). The magnetic device used was made by stacking titanium (Ti) and cobalt (Co), and alumina (Al₂O₃) was stacked as a mask. FIG. 17 illustrates the processing example using the processing apparatus 1B. FIG. 17 illustrates cross-sectional views after three types of processing such as the plasma etching only, plasma etching and gas etching (condition 1), and plasma etching and gas etching (condition 3) from the top. The gas etching conditions illustrated in FIG. 16 were adopted as the gas etching conditions. As illustrated in FIG. 17, the sidewall portion of the cobalt had a tapered shape in the case of the plasma etching only, but it was observed that the shape became closer to a vertical shape as the gas etching was applied. In particular, when the condition 3 was applied as the gas etching, the cobalt near the alumina mask was selectively removed.

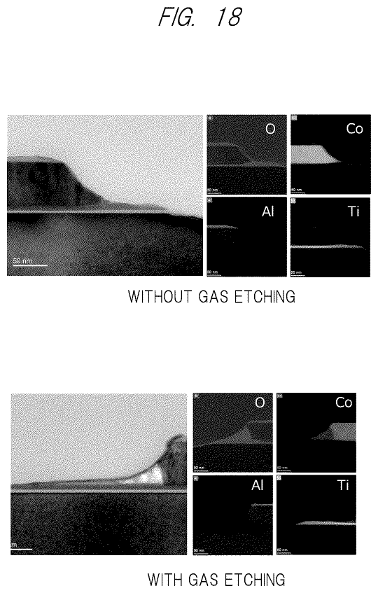

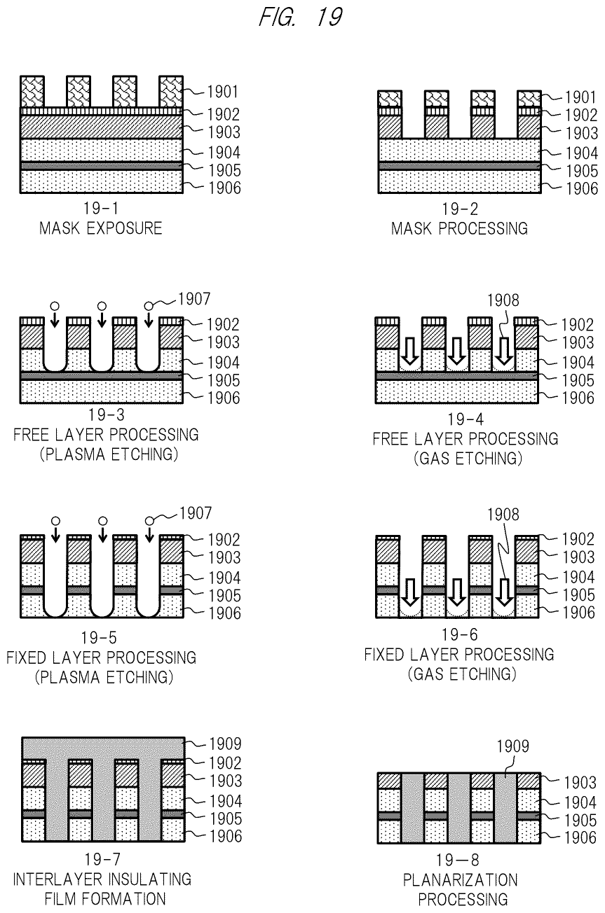

In order to verify the details of this etching, elemental analysis was performed using TEM-EDX (energy dispersive X-ray spectroscopy). FIG. 18 illustrates the results. The upper row of FIG. 18 illustrates the case without the gas etching, and the lower row of FIG. 18 illustrates the case with the gas etching. The right side of each row of FIG. 18 illustrates the analysis results of the respective elements such as oxygen (O), cobalt (Co), aluminum (Al), and titanium (Ti).

According to FIG. 18, the results were such that oxygen was widely detected along the side surface of the pattern in the case without the gas etching, but oxidation progressed only in the tapered portion of the cobalt in the case with the gas etching. Further analysis revealed that a metal complex reaction progressed in the tapered portion, and as a result, gas etching using alumina as a mask was possible.

Finally, an example of applying the above-mentioned processing method (processing apparatus) to the manufacturing process of an STT-MRAM will be described. Namely, a method of manufacturing a magnetic device will be described. FIG. 19 illustrates a schematic diagram of the manufacturing process of an MTJ (magnetic tunnel junction) element, which is a key component of the STT-MRAM. Since well-known techniques may be used for the manufacturing process of the upper electrode and lower electrode constituting the STT-MRAM, the description thereof will be omitted.

First, in a mask exposure step 19-1 illustrated in FIG. 19, a resist mask 1901 patterned by an exposure apparatus was formed on a multilayer film for the MTJ element. The multilayer film for the MTJ element was made up of a multilayer film in which mask layers 1902 and 1903, a free layer 1904, a tunnel barrier layer 1905, and a fixed layer 1906 were stacked in order. A substrate (not illustrated) was located under the fixed layer 1906.

In the example of FIG. 19, Al₂O₃ was adopted as the mask layer 1902, Ta was adopted as the mask layer 1903, and CoFeB/Ta/CoFeB was adopted as the free layer 1904. Also, MgO was adopted as the tunnel barrier layer 1905, and CoFeB/Ru/[Co/Pt stacked film] was adopted as the fixed layer 1906. Namely, a single metal of cobalt, iron, or nickel, or an alloy containing at least one of cobalt, iron, and nickel can be used as the magnetic film.

The resist pattern had a circular shape with a diameter of 30 nm, and exposure was performed with a pitch of 60 nm between the patterns.

In a mask processing step 19-2, the resist mask 1901 was temporarily transferred to a non-magnetic oxide mask Al₂O₃. The transfer method was RIE processing using mixed gas of BCl₃ and Cl₂. Then, pattering of Ta was performed using Al₂O₂ as a mask. RIE processing using Cl₂ was applied for the patterning of Ta.

In a processing step 19-3 of the free layer 1904, anisotropic etching (plasma etching) using oxygen ions 1907 was performed by the processing apparatus 1 using the multilayer mask of Al₂O₂ and Ta formed in the step 19-3. The etching by oxygen ions 1907 was terminated at the part immediately above the tunnel barrier layer 1905 by using an end point determination system.

Subsequently, as illustrated in a step 19-4, gas etching by mixed gas of acetylacetone and oxygen was performed by the processing apparatus 1. The mixed gas was irradiated from above the device by downflow (reference character 1908). The pressure and temperature conditions used in the gas etching were P=600 Pa and T=400° C. Under these conditions, it was possible to selectively remove the tapered shape at the bottom of the pattern generated in the step 19-3, and the improvement by the removal of the tapered shape was observed.

Next, the fixed layer 1906 was fabricated through a plasma etching step 19-5 and a gas etching step 19-6. The processing conditions used in the plasma etching and the gas etching were the same as those used in the formation of the free layer 1904. During the etching by oxygen ions 1907 in the step 19-5, an altered layer due to oxidation on the sidewall portion of the MTJ was observed, but the altered layer could be removed by the gas etching using the mixed gas in the step 19-6.

Next, in a step 19-7 of forming an interlayer insulating film, SiO₂ was adopted as an interlayer insulating film 1909, and planarization was performed using a CMP (Chemical Mechanical Polishing) processing in a step 19-8. At this time, the planarization processing was performed until a part of the Ta mask was exposed by the CMP processing. Through the above steps, the highly integrated MTJ element with a diameter of 30 nm and a pitch of 60 nm was successfully manufactured.

With the magnetic device manufacturing method described above, it is possible to improve the tapered shape formed in the free layer 1904 and the fixed layer 1906, making it possible to manufacture the highly integrated MTJ element.

In the foregoing, the invention made by the inventor of the present invention has been specifically described based on the embodiments, but it is needless to say that the present invention is not limited to the embodiments described above and can be modified in various ways within the range not departing from the gist thereof.

What is claimed is:

1. A method of processing a magnetic film comprising:
a first step of performing plasma etching by oxygen plasma on a workpiece on which a magnetic film is formed; and
a second step of performing gas etching using mixed gas containing oxygen and diketone after the first step,
wherein a cycle including the first step and the second step is repeated multiple times, and
wherein, in the second step, the mixed gas is irradiated in a first direction from a side that faces a surface of the workpiece.

2. The method of processing the magnetic film according to claim 1,
wherein, in the second step, the mixed gas is irradiated in a second direction different from the first direction in addition to the first direction.

3. The method of processing the magnetic film according to claim 1,
wherein the mixed gas is exhausted in the same direction as the direction in which the mixed gas is irradiated.

4. The method of processing the magnetic film according to claim 1,
wherein a non-magnetic oxide film patterned in advance is provided on the magnetic film, and the first step and the second step are performed on the magnetic film using the non-magnetic oxide film as a mask.

5. The method of processing the magnetic film according to claim 1,
wherein acetylacetone is used as diketone, and
wherein a single metal of cobalt, iron, or nickel, or an alloy containing at least one of cobalt, iron, and nickel is used as the magnetic film.

6. A method of manufacturing a magnetic device comprising:
a step of forming a multilayer film in which at least a fixed layer, a tunnel barrier layer, a free layer, and a mask layer are stacked in order on a substrate;
a step of patterning the mask layer into a predetermined pattern;
a step of processing the free layer by plasma etching using oxygen plasma using the patterned mask layer as a mask after the patterning step;
a step of processing the free layer by gas etching using mixed gas containing oxygen and diketone after the step of processing the free layer by the plasma etching;
a step of processing the tunnel barrier layer and the fixed layer by plasma etching using oxygen plasma after the step of processing the free layer by the gas etching;
a step of processing the fixed layer by gas etching using mixed gas containing oxygen and diketone after the step of processing the tunnel barrier layer and the fixed layer by the plasma etching;
a step of forming an interlayer insulating film after the step of processing the fixed layer by the gas etching; and
a step of performing a planarization processing on the interlayer insulating film formed in the step of forming the interlayer insulating film.

7. A processing apparatus comprising:
a vessel including a first gas inlet and a first gas outlet;
a sample stage on which a workpiece is placed in the vessel;
a plasma induction unit configured to induce plasma in the vessel from gas introduced from the first gas inlet;
an oxygen supply unit configured to supply oxygen to the first gas inlet;
a diketone supply unit configured to supply diketone to the first gas inlet; and
a first regulator configured to regulate the supply of the diketone from the diketone supply unit to the first gas inlet,
wherein the first gas inlet is provided in a wall surface that faces a surface of the workpiece placed on the sample stage,
wherein the first gas outlet is provided in a wall surface that faces the wall surface in which the first gas inlet is provided, and
wherein the first regulator supplies only the oxygen to the first gas inlet by regulating the supply of the diketone from the diketone supply unit when the plasma induction unit operates, and the first regulator supplies mixed gas of the oxygen and the diketone to the first gas inlet by supplying the diketone from the diketone supply unit when the plasma induction unit does not operate.

8. The processing apparatus according to claim 7,
wherein the vessel further includes a second gas inlet provided in a wall surface perpendicular to the first gas inlet and a second gas outlet provided in a wall surface that faces the second gas inlet,
the processing apparatus further comprising a second regulator configured to regulate introduction of the mixed gas from the second gas inlet, and
wherein the second regulator regulates the introduction of the mixed gas from the second gas inlet when the plasma induction unit operates, and the second regulator introduces the mixed gas from the second gas inlet when the plasma induction unit does not operate.

9. The processing apparatus according to claim 7,
wherein the plasma induction unit further includes an acceleration unit configured to accelerate ions generated in the induced plasma, and
wherein the sample stage can rotate around a rotation axis that extends in a direction perpendicular to a placement surface of the workpiece, and it is possible to change a relative angle between the rotation axis and a traveling direction of the ions.
